(19) United States
(12) Patent Application Publication
(10) Pub. No.: US 2026/0163530 A1
(43) Pub. Date: Jun. 11, 2026

(54) RADIO FREQUENCY AMPLIFIER WITH DOUBLE CASCODE STRUCTURE

(71) Applicant: BeRex Corporation Co., Ltd, Seoul (KR)

(72) Inventors: Myung Hoon CHUNG, Seoul (KR); Tae Won JUNG, Seoul (KR)

(73) Assignee: BeRex Corporation Co., Ltd, Seoul (KR)

(21) Appl. No.: 19/097,659

(22) Filed: Apr. 1, 2025

(30) Foreign Application Priority Data
Dec. 10, 2024 (KR) 10-2024-0182871

(51) Int. Cl. H03F 1/26; H03F 1/32; H03F 1/56; H03F 3/21

(52) U.S. Cl. CPC H03F 1/26; H03F 1/3205; H03F 1/565; H03F 3/211; H03F 2200/222; H03F 2200/387; H03F 2200/451; H03F 2200/54

(57) ABSTRACT

An RF amplifier with a double cascode structure may provide high gain and phase stability by simultaneously improving a gain and phase margins due to a feedback loop through which a part of an output signal is returned to an input path to improve or control specific operating characteristics in an amplifier circuit. The present disclosure has the effect of improving gain stability by controlling the gain and phase stability of a double cascode circuit by connecting a stable feedback capacitor that a feedback loop. The present disclosure provides higher gain stability and phase stability than circuits in the related art through the formation of a feedback loop and significantly improves the overall performance of the circuit through differentiated effects such as oscillation suppression, high-frequency response optimization, and noise suppression.

### CROSS-REFERENCE TO RELATED PATENT APPLICATIONS

The present application claims priority to Korean Patent Application No. 10-2024-0182871, filed Dec. 10, 2024, which is incorporated herein by reference in its entirety.

### TECHNICAL FIELD

The present disclosure relates to a radio frequency amplifier, and more particularly, to a radio frequency amplifier with a double cascode structure which provides high gain and phase stability by simultaneously improving a gain and a phase margin due to a feedback loop through which a part of an output signal is returned to an input path to improve or control specific operating characteristics in an amplifier circuit.

### BACKGROUND

Generally, cascode structures used in radio frequency (RF) power amplifiers are structures which are widely applied to the design of power amplifiers due to power conversion efficiency thereof through a high voltage gain, wide bandwidth, and high output impedance.

Particularly, cascode structures have the advantage of reducing voltage stress of a transistor, thereby reducing voltage applied to a device.

FIG. 1 is a drawing showing an example of a single cascode amplifier according to the related art and FIG. 2 is a graph showing a K-factor of a single cascode amplifier according to the related art and a graph showing a changed K-factor when a single cascode amplifier is switched to a double cascode amplifier.

A power amplifier 10 according to the related art has a structure in which one lower transistor 11 and an upper transistor 12 which is connected in series above the lower transistor 11 are provided and is in charge of function in which the two transistors are disposed in series so that the lower transistor 11 controls current and the upper transistor 12 controls voltage.

Power amplifiers according to the related art may have a disadvantage in that they may not withstand high voltage stress with only the structure of a single cascode amplifier when designing a high output power amplifier.

In order to overcome such shortcomings of the power amplifiers of the related art, if one more transistor is additionally connected in series to create a structure of a double cascode amplifier, the voltage stress generated in each transistor due to the additionally connected transistor may be distributed, thereby reducing the voltage applied to each element.

Here, as shown in FIG. 2, the double cascode amplifier, which had the performance which was achieved without issues in the single cascode amplifier structure, experiences a change in the K-factor (stability factor) when one transistor is connected in series, resulting in an unstable circuit where K<1 is obtained.

In such cases, there may be several reasons why the stability factor deteriorates. Here, the most common causes are impedance mismatch due to the size of the transistors of the cascode amplifier and insufficient gain margin or phase margin due to the structure of the cascode amplifier.

In order to solve such issues, stability is often improved through input/output impedance matching. Here, this input/output impedance matching may present a trade-off that hinders the performance of the amplifier, but may also improve stability. Furthermore, simple input/output impedance matching alone may not improve the K-factor (stability coefficient) at all.

### SUMMARY

In order to solve these issues, the present disclosure is directed to providing a radio frequency amplifier with a double cascode structure which provides high gain and phase stability by simultaneously improving a gain and a phase margin due to a feedback loop through which a part of an output signal is returned to an input path to improve or control specific operating characteristics in an amplifier circuit.

A radio frequency amplifier with a double cascode structure according to the characteristics of the present disclosure to achieve the above purpose includes a first metal-oxide-semiconductor (MOS) field-effect transistor (first MOSFET) having a first gate terminal, a first source terminal, and a first drain terminal, a second MOSFET having a second gate terminal, a second source terminal, and a second drain terminal, and a third MOSFET having a third gate terminal, a third source terminal, and a third drain terminal which are connected in series, in which the first MOSFET has an input signal terminal connected to the first gate terminal, receives an input signal through the first gate terminal, and has the first drain terminal connected to the second source terminal of the second MOSFET, the second MOSFET has the second drain terminal connected to the third source terminal of the third MOSFET, the third MOSFET outputs an output signal by connecting the third drain terminal thereof to an output signal terminal, a first feedback capacitor for increasing stability of the amplifier is connected between the third drain terminal of the third MOSFET and the second gate terminal of the second MOSFET, and a second feedback capacitor for increasing stability of the amplifier is connected between the second gate terminal of the second MOSFET and the first source terminal of the first MOSFET.

In the RF amplifier, a first capacitor for increasing stability of the amplifier may be connected between the third gate terminal of the third MOSFET and the first source terminal of the first MOSFET.

In the RF amplifier, a second capacitor for increasing stability of the amplifier may be connected between the first gate terminal of the first MOSFET and the first source terminal of the first MOSFET.

With the above-described configuration, the present disclosure has the effect of improving gain stability by controlling the gain and phase stability of the double cascode circuit by connecting a stable feedback capacitor that is a feedback loop.

The present disclosure provides higher gain stability and phase stability than circuits in the related art through the formation of a feedback loop and significantly improves the overall performance of the circuit through differentiated effects such as oscillation suppression, high-frequency response optimization, and noise suppression.

The present disclosure may connect the first feedback capacitor between the third drain terminal of the third MOSFET and the second gate terminal of the second MOSFET to suppress the gain of the amplifier from rapidly increasing or oscillating in a high frequency band and to control high frequency noise through the feedback path to ensure the gain stability of the circuit.

The present disclosure has the effect of improving the phase margin by connecting the second feedback capacitor between the second gate terminal of the second MOSFET and the first source terminal of the first MOSFET, suppressing phase shift at high frequencies and reducing instability between the feedback signal and the input signal, thereby improving the phase stability of the entire circuit.

The present disclosure shows that the first feedback capacitor and the second feedback capacitor interact with each other and form a stable feedback loop within the circuit, thereby minimizing the instability of high-frequency oscillation and excessive response characteristics that may occur in the signal path.

### BRIEF DESCRIPTION OF THE DRAWINGS

FIG. 1 is a drawing showing an example of a single cascode amplifier according to the related art.

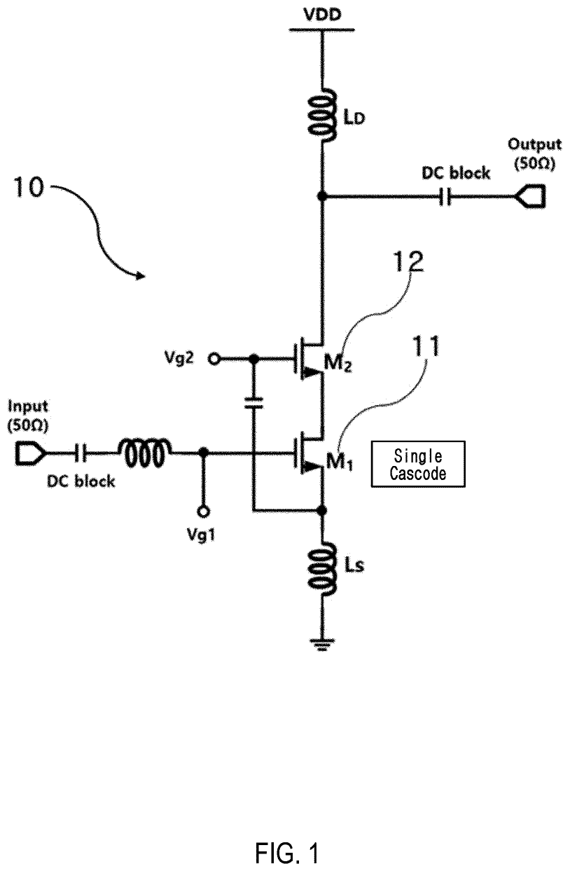

FIG. 2 is a graph showing a K-factor of a single cascode amplifier according to the related art and a graph showing a changed K-factor when a single cascode amplifier is switched to a double cascode amplifier.

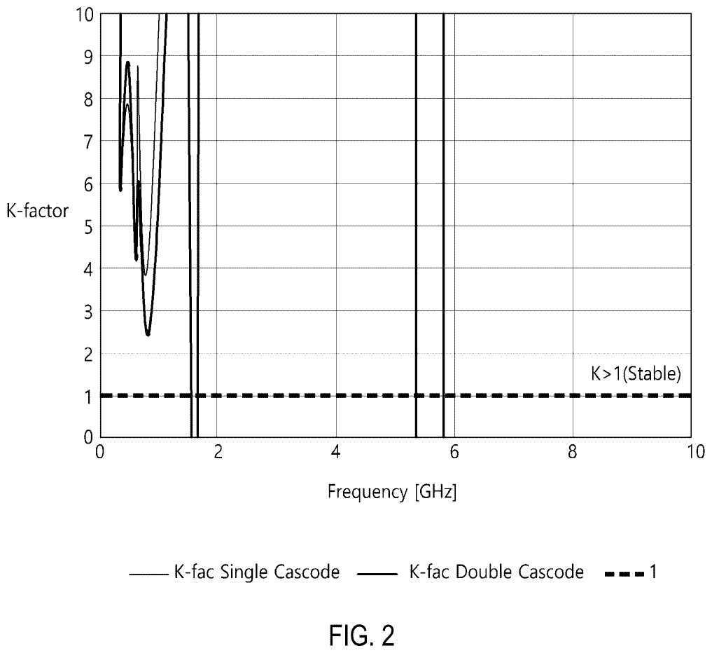

FIG. 3 is a diagram showing a configuration of a radio frequency (RF) amplifier with a double cascode structure according to an example embodiment of the present disclosure.

FIG. 4 is a diagram showing a configuration of an RF amplifier with a double cascode structure according to another example embodiment of the present disclosure.

FIG. 5 is a graph showing a state where K>1 is satisfied across the entire bandwidth by resolving the issues of an unstable region where K<1 is obtained according to an example embodiment of the present disclosure.

### DETAILED DESCRIPTION

Embodiments disclosed in this specification will be described in detail below with reference to the attached drawings. Regardless of the reference numerals used in the drawings, the same or similar constituent elements will be denoted by the same reference numerals and redundant descriptions thereof will be omitted. In addition, when describing example embodiments disclosed in this specification, if it is determined that a detailed description of a related known technique may obscure the gist of the example embodiments disclosed in this specification, the detailed description thereof will be omitted.

Although terms including ordinal numbers such as first, second, and the like may be used for describing various constituent elements, the constituent elements are not limited by the terms. The terms are used only to distinguish one constituent element from another.

Singular expressions include plural expressions unless the context clearly indicates otherwise.

In this application, each step described may be performed regardless of the listed order, except in cases in which it needs to be performed in the listed order due to a special causal relationship.

In this application, it needs to be understood that terms such as “comprises”, “includes”, or “have” are intended to specify the presence of a feature, number, step, operation, constituent element, part or combination thereof described in the specification, but do not exclude in advance the possibility of the presence or addition of one or more other features, numbers, steps, operations, constituent elements, parts or combinations thereof.

A radio frequency amplifier of the present disclosure will be described below with reference to the attached drawings.

The present disclosure is a circuit which eliminates or improves the phenomenon of oscillation or circuit stability which may occur in an amplifier circuit with a double cascode structure used for improving the high voltage stress of a radio frequency (RF) amplifier and enhance performance thereof.

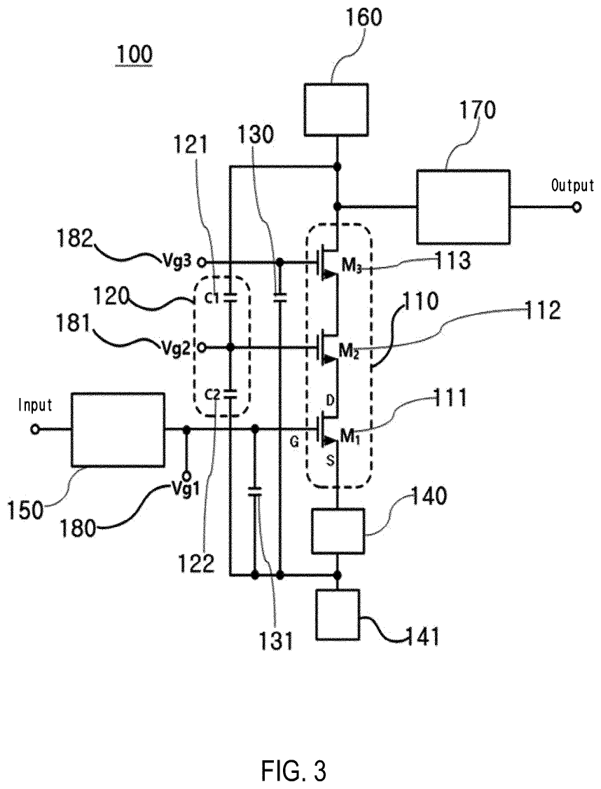

FIG. 3 is a diagram showing a configuration of a RF amplifier with a double cascode structure according to an example embodiment of the present disclosure.

An RF amplifier 100 with a double cascode structure according to an example embodiment of the present disclosure is a circuit which is designed for the purpose of amplifying a high-frequency signal and may include a transistor 110 of a double cascode amplifier circuit.

The transistor 110 of the double cascode amplifier circuit may be configured by connecting three first metal-oxide-semiconductor (MOS) field-effect transistors (first MOSFETs) 111, a second MOSFET 112, and a third MOSFET 113 in series. Such a structure may be a double cascode structure which is a double stacking of cascode structures by connecting the three transistors 111, 112, and 113 in series.

The double cascode structure maintains the linearity of the RF amplifier100, improves frequency response characteristics, and reduces instability and oscillation issues which may occur in high-frequency signals.

The RF amplifier100 operates by connecting the three transistors 111, 112, and 113 in series and each of the transistors 111, 112, and 113 performs a different role which may further improve the voltage gain and linearity of the entire circuit.

The first MOSFET 111 is an initial stage in which an input signal is received from a first gate terminal and amplified and may accommodate the largest signal change.

The first MOSFET 111 may include a first gate terminal that is a terminal for controlling a channel by applying voltage, a first drain terminal that is a terminal through which current flows out, and a first source terminal that is a terminal through which current flows in. A channel is a current path through which the first drain terminal and the second source terminal are connected and is closed using a gate voltage. The first MOSFET 111 may control the conductivity of the channel by applying voltage to the first gate terminal.

The second MOSFET 112 may include a second gate terminal that is a terminal for controlling a channel by applying voltage, a second drain terminal that is a terminal through which current flows out, and a second source terminal that is a terminal through which current flows in.

The second MOSFET 112 serves as an interface between the first MOSFET 111 and the third MOSFET 113, suppresses the influence of parasitic capacitance occurring at a first drain terminal of the first MOSFET 111 and a first gate terminal may be connected to a fixed voltage or a feedback network.

The third MOSFET 113 may include a third gate terminal that is a terminal for controlling a channel by applying voltage, a third drain terminal that is a terminal through which current flows out, and a first source terminal that is a terminal through which current flows in.

The third MOSFET 113 is responsible for the final amplification and output signal, reducing the distortion of an output signal and adjusting an output impedance of the circuit.

The first gate terminal of the first MOSFET 111 may be connected to an input signal terminal of an input matching circuit 150 of the amplifier to receive an input signal and have a gate voltage of 180 applied thereto.

The first MOSFET 111 has an input signal terminal connected to the first gate terminal and receives an input signal through the first gate terminal and a first drain terminal is connected to the second source terminal of the second MOSFET 112.

The RF amplifier 100 with a double cascode structure may secure gain and phase stability in a high-frequency band by setting a stable feedback capacitor 120 as a feedback path in a structure in which the three transistors 111, 112, and 113 are connected in series.

The stable feedback capacitor 120 forms a feedback loop between the second MOSFET 112 and the third MOSFET 113 and between the second MOSFET 112 and the first MOSFET 111, thereby achieving effects such as oscillation suppression, distortion minimization, and signal quality improvement. This allows for the implementation of a differentiated amplifier circuit with improved high-frequency performance and enhanced stability compared to existing circuits.

The stable feedback capacitor 120 may refer to a capacitor inserted in a feedback loop which a part of the output signal is returned to an input path to improve or control certain operating characteristics in the circuit.

A circuit connection structure implementing such a stable feedback capacitor 120 is as follows.

A first feedback capacitor 121 for increasing stability of the amplifier may be connected between the third drain terminal of the third MOSFET 113 and the second gate terminal of the second MOSFET 112. Here, the first feedback capacitor 121 may form a feedback path of a high-frequency signal to increase the stability of the circuit, suppress oscillation which may occur in a high-frequency region, and minimize signal distortion.

The role of the first feedback capacitor 121 is to suppress the gain of the amplifier from rapidly increasing or oscillating in the high frequency band, and particularly, to control high frequency noise through the feedback path to ensure the gain stability of the circuit.

A second feedback capacitor 122 for increasing stability of the amplifier may be connected between the second gate terminal of the second MOSFET 112 and the first source terminal of the first MOSFET 111. Here, the second feedback capacitor 122 may mainly perform the function of suppressing mutual distortion and improving linearity.

The second feedback capacitor 122 contributes to improving the phase margin, and particularly, suppresses a phase shift at high frequencies and reduces instability between the feedback signal and the input signal, thereby improving the phase stability of the entire circuit.

The first feedback capacitor 121 and the second feedback capacitor 122 interact with each other and form a stable feedback loop in the circuit, thereby minimizing high-frequency oscillation and instability of excessive response characteristics which may occur in the signal path.

The stable feedback capacitor 120 plays a key role in securing high-frequency stability in the double cascode structure and simultaneously improving the gain margin and the phase margin. The formation of such a feedback loop provides higher gain stability and phase stability than circuits in the related art and significantly improves the overall performance of the circuit through differentiated effects such as oscillation suppression, high-frequency response optimization, and noise suppression.

A first capacitor 130 for increasing stability of the amplifier may be connected between the third gate terminal of the third MOSFET 113 and the first source terminal of the first MOSFET 111. Here, the first capacitor 130 may perform a function of additionally securing stability in a high frequency band.

A second capacitor 131 for increasing stability of the amplifier may be connected between the first gate terminal of the first MOSFET 111 and the first source terminal of the first MOSFET 111. Here, the second capacitor 131 may perform a function of providing noise removal and signal quality improvement.

A degeneration circuit 140 having an inductor may be further included between the first source terminal of the first MOSFET 111 and the ground.

The degeneration circuit 140 having an inductor may be used for improving signal quality and providing stability in a high-frequency amplifier. The degeneration circuit 140 may control the operating characteristics by inserting a resistor or an inductor between the first source terminal of the first MOSFET 111 and the ground. Here, the ground may be a bonding pad 141 for ground down bonding in the drawing.

The present disclosure shows that inductors may be used for providing a more frequency-sensitive response than resistive elements and perform functions optimized for high-frequency signal processing.

The inductor of the degeneration circuit 140 has a large resistance value in the low frequency band and does not interfere with signal transmission in the high frequency band.

The inductor of the degeneration circuit 140 may reduce nonlinearity in the voltage-current characteristics of the amplifier, suppress distortion of the input signal, and thus improve the linearity of the amplifier, thereby enabling high-quality signal amplification.

The degeneration circuit 140 may adjust an input impedance and an output impedance of the amplifier by inserting an inductor into the first source terminal of the first MOSFET 111. The degeneration circuit increases the input impedance to facilitate matching with external circuits, improve signal transmission efficiency, and adjust the output impedance to enable a stable operation over a wider bandwidth.

The second MOSFET 112 may have a second drain terminal connected to the third source terminal of the third MOSFET 113, a second source terminal connected to the first drain terminal of the first MOSFET 111, and a second gate terminal to which a gate voltage of 181 is applied.

The third MOSFET 113 may have a third drain terminal connected to an output signal terminal of an output matching circuit 170 of the amplifier to output an output signal, a third source terminal connected to a second drain terminal of the second MOSFET 112, and a third gate terminal to which a gate voltage of 182 may be applied.

An inductor RF choke may be further included between the third drain terminal of the third MOSFET 113 and the power supply voltage.

A power supply circuit 160 of the amplifier circuit including an alternating current (AC) choke inductor may be further included between the drain terminal of the third MOSFET 113 and the power supply voltage.

The AC choke inductor is used as a part of the power supply circuit 160 in the amplifier circuit and plays a role in blocking or filtering high-frequency signals (AC components) while stably providing a direct current (DC) voltage.

Such an AC choke inductor plays a critical role in improving power stability and maintaining signal quality in a high-frequency amplifier.

The AC choke inductor may stably transmit a DC voltage supplied from the power supply circuit 160 to active elements (MOSFET or the like) of the amplifier circuit, block high-frequency signals from flowing back into the power supply circuit, maintain the quality of the output signal, and suppress high-frequency noise which may be introduced from the power supply circuit 160, thereby reducing interference which affects the operation of the amplifier.

The AC choke inductor may have large impedance at high frequencies, allow a DC current, block high-frequency signals, and prevent reverse flow of a signal power to maintain the stability of the circuit.

The power supply circuit 160 including the AC choke inductor may help maintain signal quality and stability of high frequency amplifier, suppress high frequency interference, stabilize power supply, and improve output signal quality.

An operation of the RF amplifier 100 is that an input signal is transmitted to the first gate terminal of the first MOSFET 111, the input signal is amplified in the first MOSFET 111, passes through the second MOSFET 112, and reaches the third MOSFET 113. In such a process, the first and second feedback capacitors may maintain the linearity of the circuit and prevent oscillation. The first and second capacitors and the inductor have the effect of improving signal quality and increasing power efficiency.

As another example embodiment, the RF amplifier 100 may have a third capacitor (not shown) for removing noise from the entire circuit connected between the third drain terminal of the third MOSFET 113 and the first source terminal of the first MOSFET 111. The formation of feedback between the output stage and the input stage has the effect of securing additional stability in the high frequency band, suppressing the possibility of residual oscillation, and extending the noise removal and linear operating range of the entire circuit.

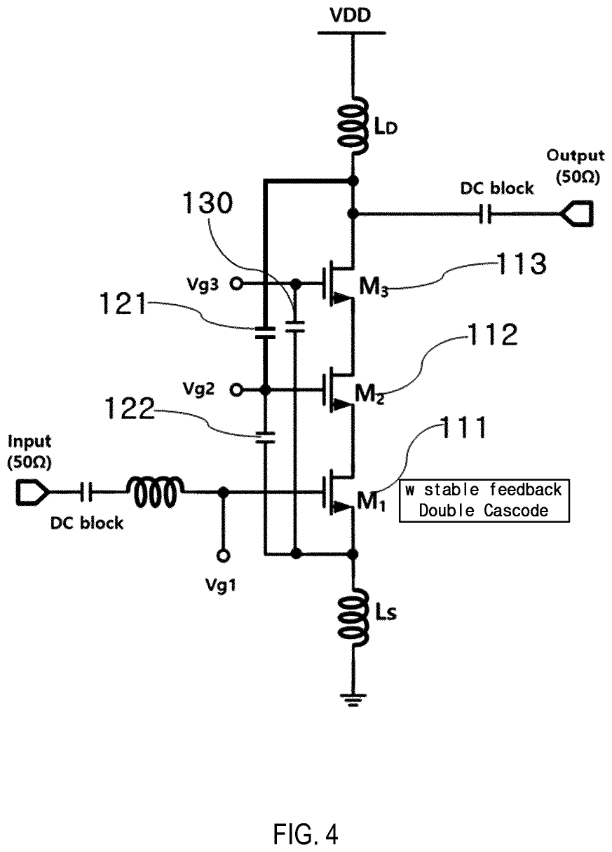

FIG. 4 is a diagram showing a configuration of an RF amplifier with a double cascode structure according to another example embodiment of the present disclosure.

Since the other example embodiment of FIG. 4 is almost the same as the example embodiment of FIG. 3 described above, a detailed description thereof is omitted. The overlapping components use the same drawing symbols and there is a difference in that the second capacitor 131 is not formed.

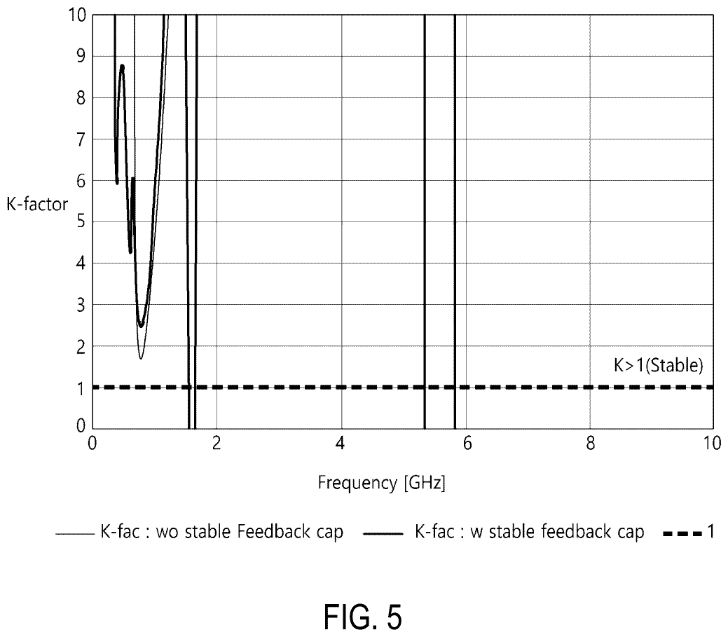

FIG. 5 is a graph showing that the issues of an unstable region of K<1 according to the example embodiment of the present disclosure has been solved and K>1 is satisfied across the entire bandwidth.

As shown in FIG. 5, the present disclosure shows that the occurrence issues of an unstable region of K<1 which occurs in a single cascode amplifier in the related art is solved and K>1 is satisfied across the entire band.

The technical features disclosed in each of the example embodiments of the present disclosure are not limited to that example embodiment, and, unless they are mutually incompatible, the technical features disclosed in each of the example embodiments may be combined and applied to other example embodiments.

Therefore, each of the example embodiments focuses on each technical feature, but unless each technical feature is incompatible with each other, it may be applied in combination with each other.

The present disclosure is not limited to the above-described example embodiments and the attached drawings and various modifications and variations may be made from the viewpoint of a person having ordinary skill in the art to which the present disclosure belongs. Accordingly, the scope of the present disclosure needs to be determined not only by the claims of this specification but also by equivalents of the claims.

What is claimed is:

1. A radio frequency (RF) amplifier, comprising
a first metal-oxide-semiconductor (MOS) field-effect transistor (first MOSFET) having a first gate terminal, a first source terminal, and a first drain terminal, a second MOSFET having a second gate terminal, a second source terminal, and a second drain terminal, and a third MOSFET having a third gate terminal, a third source terminal, and a third drain terminal which are connected in series, wherein
the first MOSFET has an input signal terminal connected to the first gate terminal, receives an input signal through the first gate terminal, and has the first drain terminal connected to the second source terminal of the second MOSFET,
the second MOSFET has the second drain terminal connected to the third source terminal of the third MOSFET,
the third MOSFET outputs an output signal by connecting the third drain terminal thereof to an output signal terminal,
a first feedback capacitor for increasing stability of the amplifier is connected between the third drain terminal of the third MOSFET and the second gate terminal of the second MOSFET, and
a second feedback capacitor for increasing stability of the amplifier is connected between the second gate terminal of the second MOSFET and the first source terminal of the first MOSFET.

2. The RF amplifier of claim 1, wherein a first capacitor for increasing stability of the amplifier is connected between the third gate terminal of the third MOSFET and the first source terminal of the first MOSFET.

3. The RF amplifier of claim 1, wherein a second capacitor for increasing stability of the amplifier is connected between the first gate terminal of the first MOSFET and the first source terminal of the first MOSFET.

4. The RF amplifier of claim 1, wherein a degeneration circuit further includes an inductor between the first source terminal of the first MOSFET and a ground.

5. The RF amplifier of claim 1, wherein a power supply circuit of an amplifier circuit including an alternating current (AC) choke inductor is further included between the third drain terminal of the third MOSFET and a power supply voltage.

6. The RF amplifier of claim 1, wherein a third capacitor for removing noise from the entire circuit is connected between the third drain terminal of the third MOSFET and the first source terminal of the first MOSFET.
